(19) United States
(12) Patent Application Publication
(10) Pub. No.: US 2024/0178752 A1
(43) Pub. Date: May 30, 2024

(54) RF CIRCUIT WITH NEGATIVE VOLTAGE GENERATION AND A METHOD FOR RF CIRCUIT CONTROL

(71) Applicant: Chengdu Sicore Semiconductor Corp. Ltd., Chengdu (CN)

(72) Inventor: Cemin Zhang, Chino, CA (US)

(73) Assignee: Chengdu Sicore Semiconductor Corp. Ltd., Chengdu (CN)

(21) Appl. No.: 18/092,521

(22) Filed: Jan. 3, 2023

(30) Foreign Application Priority Data
Nov. 29, 2022 (CN) 202211501712.2

(51) Int. Cl. H02M 3/07; H03K 3/03; H03K 17/06

(52) U.S. Cl. CPC H02M 3/071; H03K 3/0315; H03K 17/063

(57) ABSTRACT

Various embodiments for RF control circuit with negative voltage generation are disclosed. The application of a negative bias to an RF control circuit provides improved RF isolation and enhanced RF power handling capability. A negative voltage generator (NVG) with a frequency-varying clock signal is used for negative bias generation. The NVG comprises an oscillator and a negative voltage charge pump. The oscillator outputs a clock signal having a frequency varied in a span to the negative voltage charge pump, which generates a negative bias based on the frequency-varying clock signal. A level shifter receives the negative bias and outputs a shifted control signal having the negative bias. Since the clock signal has a varying frequency, the spectrum of the noise signal superimposed on the output negative bias is spread out. Consequently, noise spurs on an output RF signal are spread and suppressed, even with a high-power input RF signal.

### BACKGROUND

### A. Technical Field

The present invention relates generally to radio frequency (RF) circuit, and more particularly to RF control circuit with negative voltage generation.

### B. Background of the Invention

RF circuits have been used in many applications. N-type metal-oxide-semiconductor (NMOS) or D-mode pseudomorphic High-Electron-Mobility-Transistor (pHEMT) transistors are used as the logic switching unit for various RF control circuits, such as RF switches, RF attenuators, RF phase shifters, etc.

For a NMOS based RF switch, a “0” (switching OFF) state may require a negative voltage level applied to the gate of the NMOS switch to ideally or fully turn off the switch for improved isolation and enhanced power handling capability. Such a negative gate voltage further eliminates the need to use DC blocking capacitors in RF switches circuits. To obtain a negative gate voltage for the “0” state, a negative voltage generator (NVG) circuit is required to generate a negative bias.

Various approaches have been used for negative bias generation. A charge pump may be viewed as a type of DC-DC converter, which uses one or more capacitors as energy storage elements to create a source for a negative voltage. RF switches driven by a negative charge pump typically have a leakage current supplied through a negative voltage output of the negative charge pump. Such a leakage signal may leak or couple to an RF signal path through the chip substrate. As a result, noise spurs caused by the charge pump may undesirably impact performance of other RF circuit elements in the same chip. Furthermore, traditional negative charge pump is driven by a single fixed frequency clock signal. Strong noise spurs may occur around an RF signal frequency due to modulation between the leaked signal at the fixed clock frequency and the RF signal. It may be difficult to filter those strong noise spurs due to the narrow frequency gap between the strong noise spurs and the RF signal, especially when the RF signal is at a high frequency.

Accordingly, there is a need for systems and methods for providing RF control circuit with negative voltage to address the above issues for improved performance.

### SUMMARY OF THE INVENTION

The present disclosure provides system and method embodiments for RF control circuit with negative voltage generation. The application of a negative bias to an RF control circuit provides improved isolation and enhanced power handling capability.

In one or more embodiments, a negative voltage generator (NVG) with a frequency-varying clock signal is used for negative bias generation. The NVG comprises an oscillator and a negative voltage charge pump. The oscillator outputs a clock signal having a frequency varied in a span from a lowest frequency F₁ to a highest frequency F₂ to the negative voltage charge pump, which generates a negative bias based on the clock signal. A level shifter receives the negative bias and outputs a shifted control signal based on a control signal, which usually has a positive voltage for logic “1” or a zero (or near-zero) voltage for logic “0”. The level shifter shifts the zero or near-zero voltage for logic “0” into the negative bias. As a result, the shifted control signal provides the negative bias for logic “0” for improved switching control of an RF control circuit, e.g., an RF switch.

Since the clock signal has a frequency varied from F₁ to F₂, the noise signal superimposed on the output negative bias is also spread out from F₁ to F₂. Consequently, noise spurs on an output RF signal of the RF switch are spread and also significantly reduced, even when the RF switch has an input RF signal having high RF power.

In one or more embodiments, the oscillator for the NVG may be a resistor-capacitor (RC) oscillator comprising a first inverter and a second inverter coupled in series. The RC oscillator outputs an output clock signal, which couples a first output voltage from the first inverter and a second output voltage of the second inverter via a variable resistor and a variable capacitor, respectively. The output clock signal is also fed back as an input to the first inverter. The variable resistor and the variable capacitor may be adjusted via switch banks such that the frequency of the output clock signal varies among multiple selections. Alternatively, the oscillator outputting a frequency-varying clock signal may comprise an oscillator outputting a fixed-frequency clock signal and a frequency divider having a variable frequency-division ratio. The frequency of the output clock signal may vary by adjusting the frequency-division ratio of the frequency divider. With the frequency-varying clock signal for negative bias generation, noise spurs leaked to the RF control circuit may be spread out and thus be suppressed collectively.

For the purpose of summarizing the present disclosure, certain aspects and novel features of the inventions have been described herein. One skilled in the art shall recognize that embodiments disclosed in this invention document may be implemented with various permutations, enhancements, equivalents, combinations, and improvements, all of which should fall within the scope of the present invention.

### BRIEF DESCRIPTION OF THE DRAWINGS

Reference will be made to exemplary embodiments of the present invention that are illustrated in the accompanying figures. Those figures are intended to be illustrative, rather than limiting. Although the present invention is generally described in the context of those embodiments, it is not intended by so doing to limit the scope of the present invention to the particular features of the embodiments depicted and described.

FIG. 1 depicts a prior art negative voltage generator.

FIG. 2 depicts a negative voltage generator using a fixed-frequency clock signal for negative bias generation.

FIG. 3 depicts spurs in spectrums for RF output signals from a RF switch having a negative gate control voltage supplied from a negative voltage generator with fixed-frequency clock signal.

FIG. 4 depicts a negative voltage generator using a frequency-varying clock signal for negative bias generation, according to one or more embodiments of the invention.

FIG. 5 depicts spurs in spectrums for RF output signals from an RF switch having a negative gate control voltage supplied from a negative voltage generator with a frequency-varying clock signal, according to one or more embodiments of the invention.

FIG. 6 depicts a resistor-capacitor (RC) oscillator that generates a frequency-varying clock signal, according to one or more embodiments of the invention.

FIG. 7 depicts an oscillator with a frequency divider to generate a frequency-varying clock signal, according to one or more embodiments of the invention.

FIG. 8 depicts a process of using negative voltage for RF circuit control, according to one or more embodiments of the invention.

One skilled in the art will recognize that various implementations and embodiments of the invention may be practiced in accordance with the specification. All of these implementations and embodiments are intended to be included within the scope of the invention.

### DETAILED DESCRIPTION

In the following description, for purpose of explanation, specific details are set forth in order to provide an understanding of the present invention. The present invention may, however, be practiced without some or all of these details. The embodiments of the present invention described below may be incorporated into a number of different electrical components, circuits, devices, and systems. Structures and devices shown in block diagrams are illustrative of exemplary embodiments of the present invention and are not to be used as a pretext by which to obscure broad teachings of the present invention. Connections between components within the figures are not intended to be limited to direct connections. Rather, connections between components may be modified, re-formatted, or otherwise changed by intermediary components.

When the specification makes reference to “one embodiment” or to “an embodiment” it is intended to mean that a particular feature, structure, characteristic, or function described in connection with the embodiment being discussed is included in at least one contemplated embodiment of the present invention. Thus, the appearance of the phrase, “in one embodiment,” in different places in the specification does not constitute a plurality of references to a single embodiment of the present invention. Each reference/document mentioned in this patent document is incorporated by reference herein in its entirety. It shall be noted that any examples provided herein are provided by way of illustration and were performed under specific conditions using a specific embodiment or embodiments; accordingly, neither these examples shall be used to limit the scope of the disclosure of the current patent document.

N-type metal-oxide-semiconductor (NMOS) or D-mode pseudomorphic High-Electron-Mobility-Transistor (pHEMT) transistors have been widely used as the logic switching unit for various RF control circuits, such as RF switches, RF attenuators, RF phase shifters, etc. For an NMOS-based RF switch, a negative voltage level applied to the gate of the NMOS switch may be desired to ideally or fully turn off the switch for improved isolation and enhanced power handling capability. Such a negative gate voltage may eliminate the need of using DC blocking capacitors in RF control circuits such that the RF control circuits can operate from DC to RF frequencies. To obtain a negative gate voltage for the ‘0’ state, a negative voltage generator (NVG) circuit is required to generate a negative bias.

Negative bias may be generated using various approaches, e.g., by a combination of an oscillator and a charge pump. The charge pump may be viewed as a type of DC-DC converter, which may use one or more capacitors as energy storage elements to create a source for a negative voltage. RF switches driven by a negative charge pump typically have a leakage current supplied through a negative voltage output of the negative charge pump. Such a leakage signal may leak or couple to an RF signal path through chip substrate. As a result, noise spurs caused by the charge pump may undesirably impact performance of other RF circuit elements in the same chip.

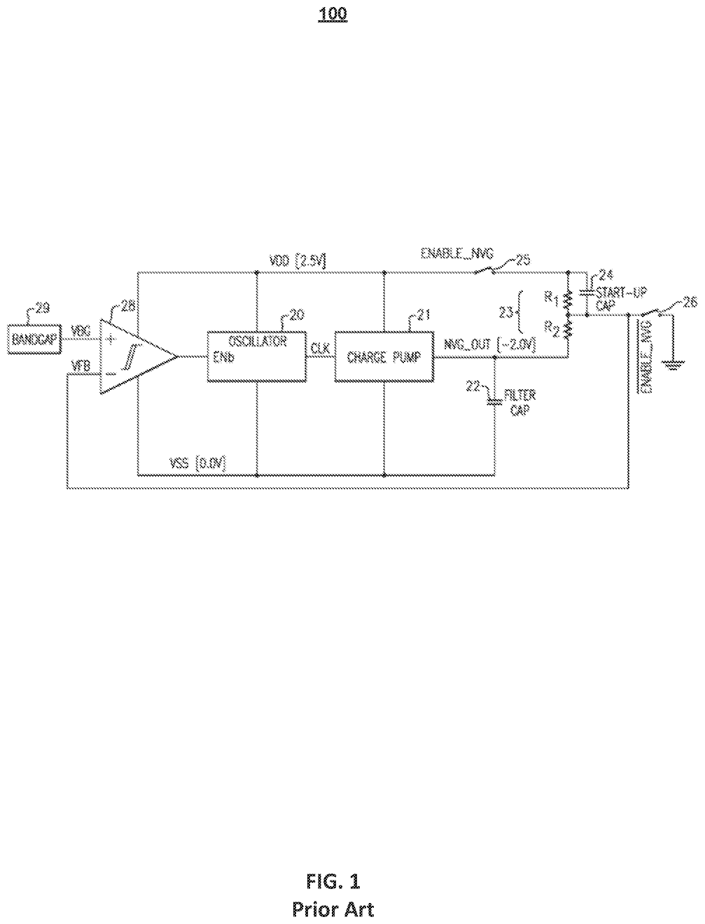

U.S. Pat. No. 9,467,124B2 discloses a negative voltage generator, as shown in FIG. 1. The voltage generator includes an oscillator 20, a charge pump 21, a filter capacitor 22, a voltage divider 23, a start-up capacitor 24, a first enable switch 26, a second enable switch 25, a comparator 28, and a voltage reference generator 29. The charge pump 21 can generate a negative voltage NVG_OUT based on the clock signal CLK provided by the oscillator 20. The oscillator outputs a clock signal CLK at a clock frequency, the negative voltage generated by the charge pump may have a noise voltage clocking at the clock frequency. The noise voltage may be leaked to RF control circuit and be modulated to input RF signal, especially when the input RF signal is in high power level and the RF transistors are more prone to nonlinear conditions.

### Embodiment 1

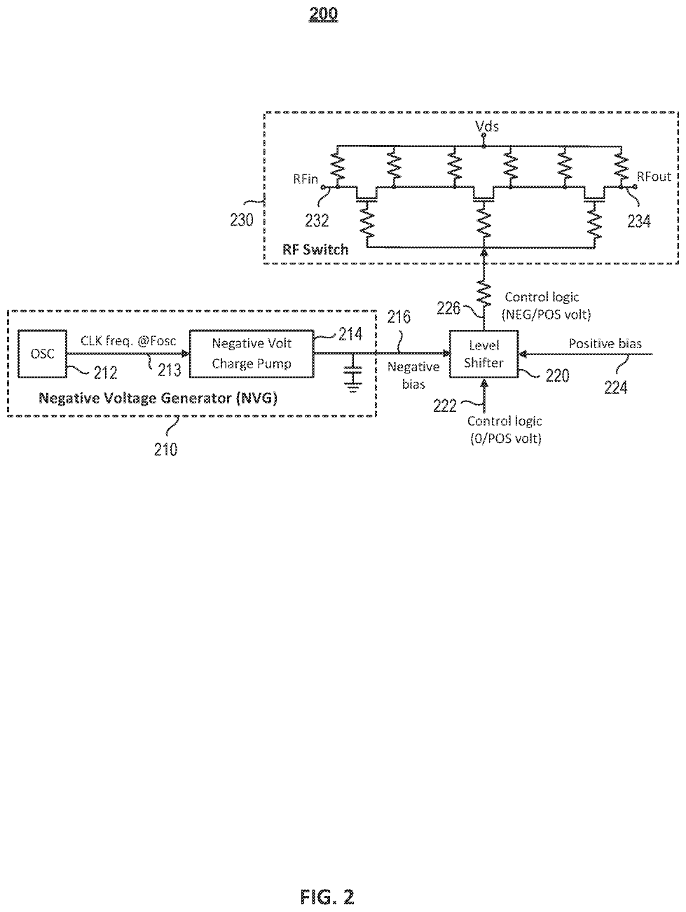

FIG. 2 depicts a negative voltage generator (NVG) using a fixed-frequency clock signal for negative bias generation. The NVG 210 comprises an oscillator 212 and a negative voltage charge pump 214. The oscillator 212 outputs a clock signal 213 at a fixed clock frequency F_{OSC} to the negative voltage charge pump 214, which generates a negative bias 216 based on the clock signal 213. A level shifter 220 receives the negative bias 216 and the positive bias 224, and outputs a shifted control signal 226 based on a control signal 222, which usually has a first positive voltage for logic “1” or a zero (or near-zero) voltage for logic “0”.

The level shifter 220 shifts the first positive voltage for logic “1” into a second positive voltage based on the positive bias 224 and shifts the zero or near-zero voltage for logic “O” into a negative voltage based on the negative bias 216, such that the shifted control signal 226 provides the positive bias for logic “1” and the negative bias for logic “0” for improved switching control of the RF switch 230. In one or more embodiments, the near-zero voltage is referring to a voltage level between 0V and 1V.

The oscillator 212 operates at a fixed frequency F_{OSC}, and the clock signal 213 can be superimposed on the output negative bias 216 as an alternative current (AC) noise voltage, which can leak to the RF switch circuit 230 and be modulated to the input RF signal 232, especially when the input RF signal 232 has a high power level and the RF transistor(s) are more prone to nonlinear conditions. As a result, the output RF signal 234 may have undesired noise spurs.

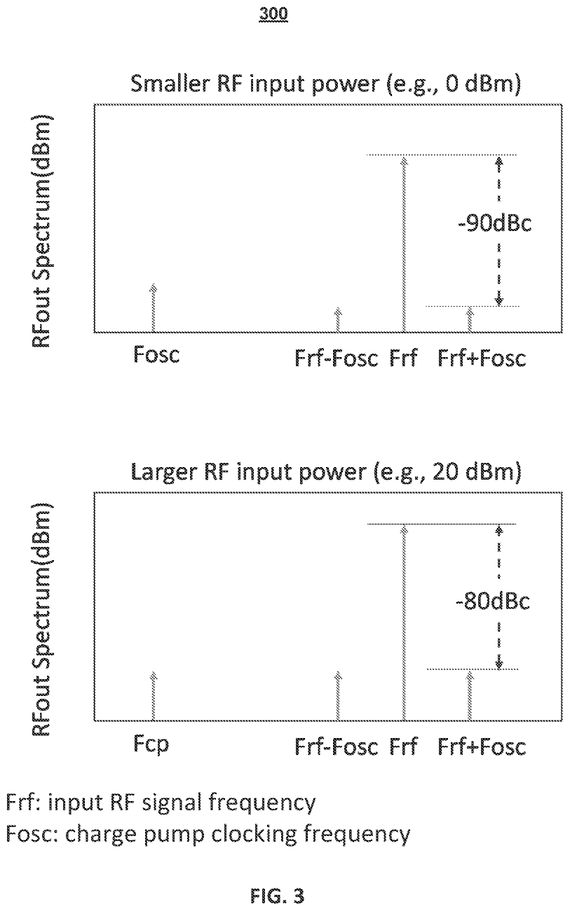

FIG. 3 depicts spurs in spectrums for RF output signals from a RF switch having a negative gate control voltage supplied from a negative voltage generator with a fixed-frequency clock signal. The RF output signal has noise spurs at the clock signal frequency F_{OSC} and frequencies near RF signal frequency, e.g., F_{RF}+F_{OSC} and F_{RF}−F_{OSC}, due to modulation between the RF input signal and the clock signal leaked or coupled to an RF signal path of the RF switch. The higher RF input power, the more nonlinearity of the RF switch, and thus the worse of the noise spurs. As shown in FIG. 3, when the input RF signal has a small RF power, e.g., 0 dBm, the noise spurs at F_{RF}+F_{OSC} and F_{RF}−F_{OSC} have −90 dBc power ratio to the RF carrier signal at F_{RF}. When the input RF signal has larger RF power, e.g., 20 dBm, the noise spurs at F_{RF}+F_{OSC} and F_{RF}−F_{OSC} increase to −80 dBc power ratio to the RF carrier signal at F_{RF}.

In many RF systems, the spur level needs to be lower than −100 dBc power ratio to the RF carrier signal at F_{RF}. Furthermore, when the RF signal frequency F_{RF} is much higher than the clock signal frequency F_{OSC}, the noise spurs at F_{RF}+F_{OSC} and F_{RF}−F_{OSC} would be very difficult to be removed due to the narrow frequency differences between the RF signal and the noise spurs. Extra filters are needed to remove those noise spurs, thus adding overall cost and complexity for the RF systems. Furthermore, the traditional approach of filtering or regulating the negative voltage of the NVG to reduce the clock signal injection to the RF path would be difficult in an integrated chip due to substrate leakage.

Described herein are system and method embodiments of using negative voltage for gate control in RF circuits for improved performance. Instead of using a clock signal having a single frequency F_{OSC} in an NVG, which leads to a strong single-tone noise spur, embodiments of NVG using a clock signal with varied frequencies are disclosed in the present document. Under varied frequencies, the clock signal superimposed on the negative voltage output from NVG is spread over a frequency span. As a result, noise spurs can be significantly reduced or suppressed.

### Embodiment 2

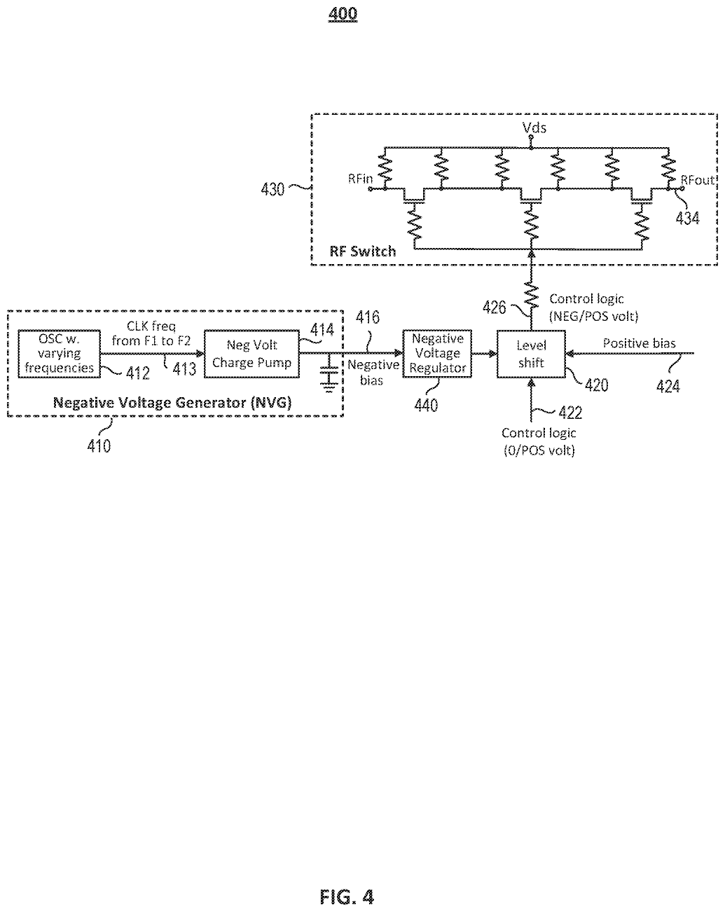

FIG. 4 depicts a negative voltage generator with a frequency-varying clock signal for negative bias generation, according to one or more embodiments of the invention. The NVG 410 comprises an oscillator 412 and a negative voltage charge pump 414. The oscillator 412 outputs a clock signal 413 having a frequency varied in a span from a lowest frequency F₁ to a highest frequency F₂ to the negative voltage charge pump 414, which generates a negative bias 416 based on the clock signal 413. A level shifter 420 receives the negative bias 416 and the positive bias 424 and outputs a shifted control signal 426 based on a control signal 422, which usually has a first positive voltage for logic “1” or a zero (or near-zero) voltage for logic “0”. In one or more embodiments, the near-zero voltage is referring to a voltage level between 0V and 1V. The negative bias 416 and the positive bias 424 may have the same or different absolute voltage levels. For example, the positive bias 424 for logic “1” may be +3V, while the negative bias 416 may be −3.3V.

The level shifter 420 shifts the first positive voltage for a first logic, e.g., logic “1”, into a second positive voltage based on the positive bias 424 and shifts the zero or near-zero voltage for a second logic, e.g., logic “0”, into a negative voltage based on the negative bias 416. As a result, the shifted control signal 426 provides the second positive voltage for the first logic and the negative voltage for the second logic for improved switching control of the RF switch 430.

The Level shifter may receive the negative bias 416 directly or indirectly. In one or more embodiments, a negative voltage regulator 440 may be incorporated between the NVG 410 and the level shifter 420 to regulate the negative bias 416 before feeding to the level shifter 420.

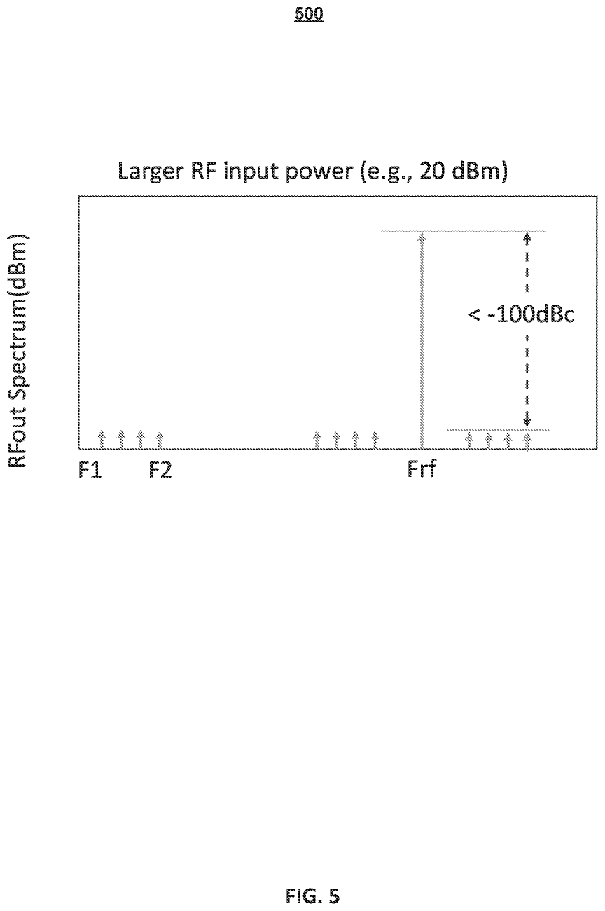

Since the clock signal 413 has a frequency varied in a span from F₁ to F₂, the noise signal superimposed on the output negative bias 416 is also spread out from F₁ to F₂. Consequently, noise spurs on the output RF signal 434 of the RF switch 430 are spread and also significantly reduced, as shown in the spectrum of spurs in FIG. 5. Even with input RF signal having high RF power, e.g., 20 dBm, the noise spurs are spread out, thus have lowered spurious power level, e.g., less than −100 dBc power ratio to the RF carrier signal at F_{RF}.

### Embodiment 3

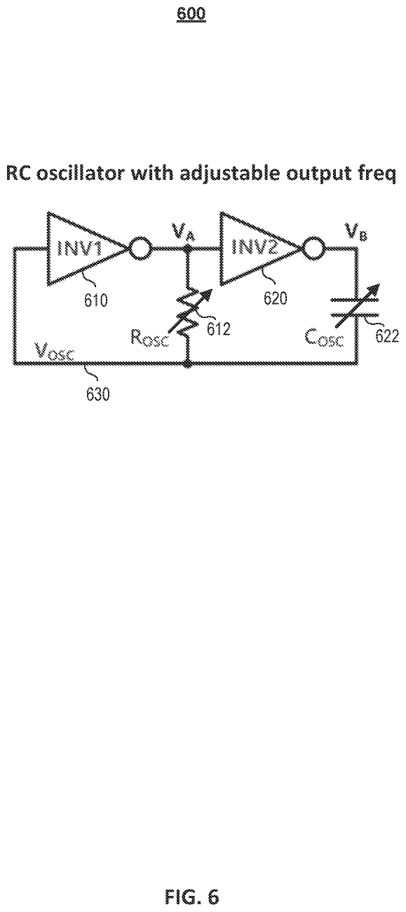

The frequency-varying oscillator may have various configurations, such as a frequency-varying RC oscillator, a frequency-varying ring oscillator, a frequency-varying inductor-capacitor (LC) oscillator, a frequency synthesizer, etc. FIG. 6 depicts an RC oscillator that generates a frequency-varying clock signal, according to one or more embodiments of the invention. The RC oscillator comprises a first inverter 610, a second inverter 620 coupled in series to the first inverter 610, a variable resistor R_{OSC} 612, and a variable capacitor C_{OSC} 622. The second inverter 620 receives a first output voltage VA from the first inverter 610 and outputs a second output voltage VB. An oscillator output V_{OSC} 630, which may be the output clock signal, couples the first output voltage VA and the second output voltage VB via the variable resistor R_{OSC} 612 and the variable capacitor C_{OSC} 622, respectively, and is fed back as an input to the first inverter 610. In one or more embodiments, the first output voltage VA from the first inverter 610 or the second output voltage VB, instead of V_{OSC} 630, may be used as the output signal from the RC oscillator.

In one or more embodiments, the variable resistor R_{OSC} 612 and the variable capacitor C_{OSC} 622 may be adjusted via switch banks. For example, the variable resistor R_{OSC} 612 may have M values or states, and the variable capacitor C_{OSC} 622 may have N values or states. The RC oscillator thus has M×N state combinations for frequencies of the oscillator output V_{OSC}. The state selection may be controlled by a state machine or a state controller. Generally, the more states of choice, the more frequency spreading for the output clock signal, and the more reduction for the power level of each clock frequency state. Eventually, the power levels of the noise spurs are collectively reduced, as shown in FIG. 5.

The RC oscillator may vary state combinations in a desired manner such that the output clock signal may have a clock frequency varying in a desired pattern, e.g., varying from the lowest frequency F₁ to the highest frequency F₂, from the highest frequency F₂ to the lowest frequency F₁, or randomly varying in the span between the lowest frequency F₁ and the highest frequency F₂. The operation interval at each clock frequency may or may not be the same, and may be dynamically adjusted or programmed based on noise spurs appearing in the spectrum of the RF output signal in the RF control circuit. For example, when a specific noise spur stands out among multiple noise spurs, the RC oscillator may be adjusted such that the operation interval at a clock frequency related to the particular noise spur is decreased or even eliminated. In other words, the clock frequency may vary with one or more frequencies between the lowest frequency to the highest frequency skipped.

### Embodiment 4

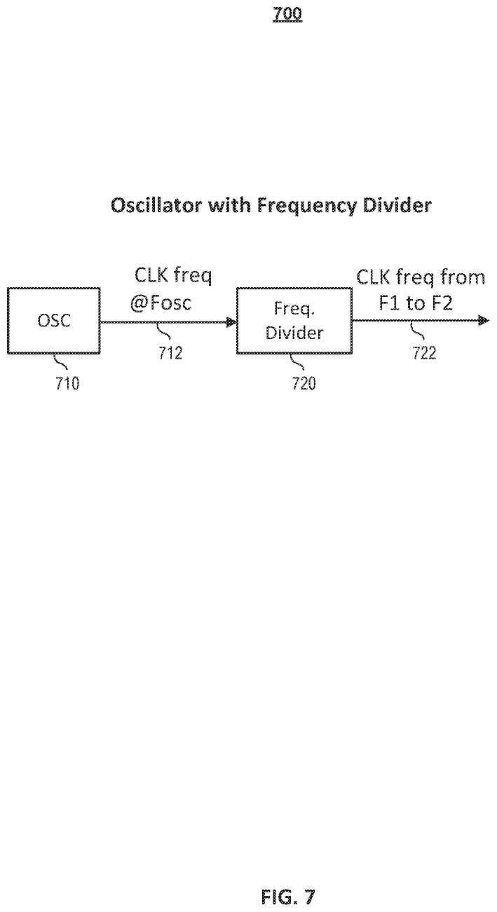

FIG. 7 depicts an oscillator with a frequency divider to generate a frequency-varying clock signal, according to one or more embodiments of the invention. A fixed-frequency oscillator 710 and A frequency divider 720 jointly function as one oscillator outputting a frequency-varying clock signal. The fixed-frequency oscillator 710 outputs a clock signal 712 having a fixed frequency F_{OSC} to a frequency divider 720, which has a variable frequency-division ratio. The frequency divider 720 may be an integer divider or a fractional divider, and its frequency-division ratio may be controlled by a state machine or a state controller. Accordingly, depending on the frequency-division ratio, the clock signal output 722 from the frequency divider 720 may vary in frequency from F₁ to F₂. Although the fixed-frequency oscillator 710 is used, the fixed-frequency clock signal is used to drive the frequency divider, instead of feeding to the charge pump directly. Therefore, the single-tone noise spur showing in FIG. 3 may still be effectively prevented.

Similar to the implementation of the RC oscillator, the frequency divider may vary state combinations in a desired manner such that the output clock signal may have a clock frequency varying in a desired pattern, e.g., varying from the lowest frequency F₁ to the highest frequency F₂, from the highest frequency F₂ to the lowest frequency F₁, or randomly varying in the span between the lowest frequency F₁ and the highest frequency F₂. The operation interval at each clock frequency may or may not be the same, and may be dynamically adjusted or programmed based on noise spurs appearing in the spectrum of the RF output signal in the RF control circuit.

Although FIG. 6 and FIG. 7 disclose two embodiments of generating a frequency-varying clock signal for negative bias generation, one skilled in the art shall understand that a clock signal with varied frequencies may be generated using other approaches, such as a frequency-varying ring oscillator, a frequency-varying LC oscillator, a frequency synthesizer, or a combination of the embodiments shown in FIG. 6 and FIG. 7. The control of state combinations for the RC oscillator may also be applicable to other types of frequency-varying oscillators. Additionally, a certain type of frequency-varying oscillator may be used together with a frequency divider to further spread the clock frequency for decreasing noise spurs in the RF output signal.

### Embodiment 5

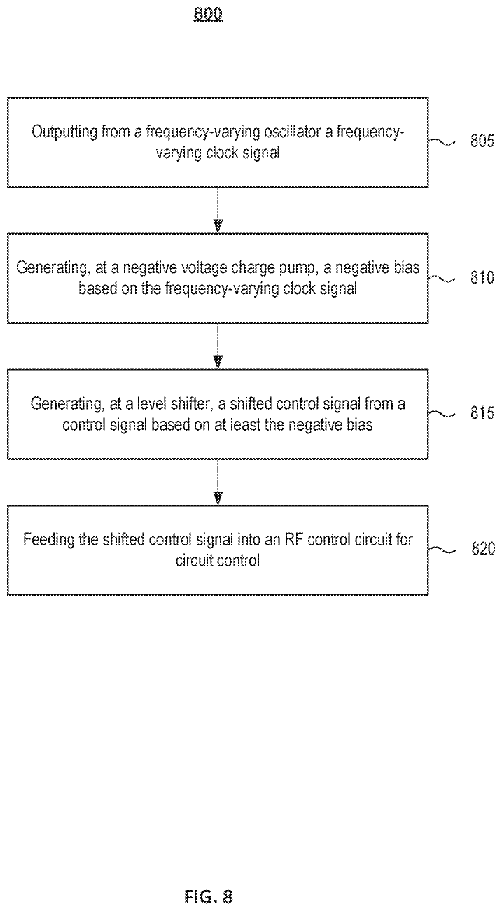

FIG. 8 depicts a process of using negative voltage for RF circuit control, according to one or more embodiments of the invention. In step 805, a frequency-varying clock signal is output from a frequency-varying oscillator, which may be an RC oscillator, a combination of a fixed-frequency oscillator and a variable ratio frequency divider. In step 810, a negative bias is generated at a negative voltage charge pump based on the frequency-varying clock signal.

In step 815, a shifted control signal is generated at a level shifter from a control signal based on at least the negative bias. The control signal has a first positive voltage for a first logic state and a zero or near-zero voltage for a second logic state. The first logic state and the second logic state may be “1” and “0” respectively, or vice versa. The zero or near-zero voltage for the second logic state is shifted into a negative voltage based on the negative bias in the shifted control signal. In one or more embodiments, the level shifter receives a positive bias in addition to the negative bias. The first positive voltage for the first logic state is shifted into a second positive voltage based on the positive bias in the shifted control signal. The positive bias and the negative bias may have the same or different absolute voltage levels. The first positive voltage and the second positive voltage may have the same or different voltage levels.

In step 820, the shifted control signal is fed into an RF control circuit for circuit control. The RF control circuit may be an RF switch as shown in the exemplary embodiments shown in FIG. 4, or other types of RF control circuit, e.g., an RF phase shifter, an RF attenuator, etc.

The foregoing description of the invention has been described for purposes of clarity and understanding. It is not intended to limit the invention to the precise form disclosed. Various modifications may be possible within the scope and equivalence of the appended claims.

It will be appreciated to those skilled in the art that the preceding examples and embodiments are exemplary and not limiting to the scope of the present invention. It is intended that all permutations, enhancements, equivalents, combinations, and improvements thereto that are apparent to those skilled in the art upon a reading of the specification and a study of the drawings are included within the true spirit and scope of the present invention.

It shall also be noted that elements of the claims, below, may be arranged differently including having multiple dependencies, configurations, and combinations. For example, in embodiments, the subject matter of various claims may be combined with other claims.

1. A radio-frequency (RF) circuit with negative voltage generation comprising:
a frequency-varying oscillator outputting a frequency-varying clock signal that has a clock frequency varying in a span between a lowest frequency to a highest frequency;
a negative voltage charge pump coupled to the frequency-varying oscillator, the negative voltage charge pump generates a negative bias based on the frequency-varying clock signal;
a level shifter coupled to the negative voltage charge pump, the level shifter coupled to receive the negative bias and a control signal to generate a shifted control signal, the control signal has a first positive voltage for first logic state and a zero or near-zero voltage for a second logic state, the shifted control signal has a negative voltage based on the negative bias for the second logic state; and
an RF control circuit receiving the shifted control signal for RF control operation.

2. The RF circuit with negative voltage generation of claim 1, wherein the RF control circuit is an RF switch, an RF attenuator, or an RF phase shifter, or a combination thereof.

3. The RF circuit with negative voltage generation of claim 1 further comprising:
a negative voltage regulator incorporated between the negative voltage charge pump and the level shifter to regulate the negative bias.

4. The RF circuit with negative voltage generation of claim 1, wherein the frequency-varying oscillator is a frequency-varying resistor-capacitor (RC) oscillator, a frequency-varying ring oscillator, a frequency-varying inductor-capacitor (LC) oscillator, or a frequency synthesizer, or a combination thereof.

5. The RF circuit with negative voltage generation of claim 4, wherein the frequency-varying oscillator is controlled by a state machine or a state controller for state selection such that the clock frequency of the frequency-varying clock signal varies in a desired pattern.

6. The RF circuit with negative voltage generation of claim 1, wherein the frequency-varying oscillator comprising:
a fixed-frequency oscillator outputting a fixed-frequency clock signal; and
a frequency divider having a variable frequency-division ratio, the frequency divider receives the fixed-frequency clock signal and outputs the frequency-varying clock signal.

7. The RF circuit with negative voltage generation of claim 1, wherein the clock frequency varies in a desired pattern of:
varying from the lowest frequency to the highest frequency;
varying from the highest frequency to the lowest frequency; or
randomly varying between the lowest frequency and the highest frequency.

8. The RF circuit with negative voltage generation of claim 1, wherein the clock frequency varies with one or more frequencies between the lowest frequency to the highest frequency skipped.

9. The RF circuit with negative voltage generation of claim 1, wherein the frequency-varying clock signal has the clock frequency varying among a plurality of frequencies between the lowest frequency to the highest frequency with interval at each of the plurality of frequencies the same or different.

10. The RF circuit with negative voltage generation of claim 1, wherein the level shifter further receives a positive bias, the shifted control signal has a second positive voltage based on the positive bias for the first logic state.

11. A method for radio-frequency (RF) circuit control with negative voltage generation comprising following steps:
outputting, from a frequency-varying oscillator, a frequency-varying clock signal that has a clock frequency varying in a span between a lowest frequency to a highest frequency;
generating, at a negative voltage charge pump coupled to the frequency-varying oscillator, a negative bias based on the frequency-varying clock signal;
generating, at a level shifter coupled to the negative voltage charge pump, a shifted control signal based on at least the negative bias and a control signal, the control signal has a first positive voltage for first logic state and a zero or near-zero voltage for a second logic state, the shifted control signal has a negative voltage based on the negative bias for the second logic state; and
receiving, at an RF control circuit, the shifted control signal for RF control operation.

12. The method of claim 11, wherein the RF control circuit is an RF switch, an RF attenuator, or an RF phase shifter, or a combination thereof.

13. The method of claim 11, wherein the frequency-varying oscillator, the negative voltage charge pump, the level shifter, and the RF control circuit are integrated in one single chip.

14. The method of claim 11, wherein the frequency-varying oscillator is a frequency-varying resistor-capacitor (RC) oscillator, a frequency-varying ring oscillator, a frequency-varying inductor-capacitor (LC) oscillator, or a frequency synthesizer, or a combination thereof.

15. The method of claim 14, wherein the frequency-varying oscillator is controlled by a state machine or a state controller for state selection such that the clock frequency of the frequency-varying clock signal varies in a desired pattern.

16. The method of claim 11, wherein the frequency-varying oscillator comprising:
a fixed-frequency oscillator that outputs a fixed-frequency clock signal; and
a frequency divider having a variable frequency-division ratio, the frequency divider receives the fixed-frequency clock signal and outputs the frequency-varying clock signal.

17. The method of claim 11, wherein the clock frequency varies in a desired pattern of:
varying from the lowest frequency to the highest frequency;
varying from the highest frequency to the lowest frequency; or
randomly varying between the lowest frequency and the highest frequency.

18. The method of claim 11, wherein the clock frequency varies with one or more frequencies between the lowest frequency to the highest frequency skipped.

19. The method of claim 11, wherein the frequency-varying clock signal has the clock frequency varying among a plurality of frequencies between the lowest frequency to the highest frequency with interval at each of the plurality of frequencies the same or different.

20. The method of claim 11, wherein the shifted control signal has a second positive voltage for the first logic state, the second positive voltage is based on the positive bias received at the level shifter.
